(19) United States
(12) Patent Application Publication
(10) Pub. No.: US 2013/0344641 A1
(43) Pub. Date: Dec. 26, 2013

(54) MECHANICAL AND CHEMICAL TEXTURIZATION OF A SILICON SHEET FOR PHOTOVOLTAIC LIGHT TRAPPING

(71) Applicant: CORNING INCORPORATED, Corning, NY (US)

(72) Inventors: Glen Bennett Cook, Elmira, NY (US); Kamal Kishore Soni, Painted Post, NY (US); Christopher Scott Thomas, Horseheads, NY (US); Lili Tian, Corning, NY (US)

(73) Assignee: CORNING INCORPORATED., Corning, NY (US)

(21) Appl. No.: 13/841,109

(22) Filed: Mar. 15, 2013

Related U.S. Application Data
(60) Provisional application No. 61/664,225, filed on Jun. 26, 2012.

(51) Int. Cl. H01L 31/18

(52) U.S. Cl. CPC H01L 31/1824
USPC 438/71

(57) ABSTRACT

A process for modifying a surface of a cast polycrystalline silicon sheet to decrease the light reflectance of the cast polycrystalline sheet is disclosed. The cast polycrystalline silicon sheet has at least one structural feature resulting from the cast polycrystalline silicon sheet being directly cast to a thickness less than 1000 micrometers. The process comprises grit blasting the surface of the cast polycrystalline silicon sheet to give an abraded surface on the cast polycrystalline silicon sheet. The process further comprises chemically etching the abraded surface of the cast polycrystalline silicon sheet to give a chemically-etched, abraded surface. The light reflectance of the chemically-etched, abraded surface is decreased in comparison to the light reflectance of the surface of the cast polycrystalline silicon sheet before the step of grit blasting.

### CROSS-REFERENCE TO RELATED APPLICATIONS

This application claims the benefit of priority under 35 U.S.C. §119 of U.S. Provisional Application Ser. No. 61/664,225 filed on Jun. 26, 2012, the content of which is relied upon and incorporated herein by reference in its entirety.

### FIELD

The present disclosure generally relates to a process for modifying a surface of a cast polycrystalline silicon sheet. More specifically, the disclosure relates to a process for modifying the surface of the cast polycrystalline silicon sheet which has been directly cast into a thickness of less than 1000 micrometers.

### BACKGROUND

Silicon sheets are commonly-used in photovoltaic applications to facilitate light trapping in solar cells. One of the characteristics that affect the efficiency of such solar cells is the ability of the silicon sheets to trap light. Conventionally, large silicon ingots were sawn into thin silicon sheets. This sawing created saw damage on the surface of the thin silicon sheets. The thus formed thin silicon sheets were often treated with an etching solution to improve their light trapping ability. The saw damage on the surface of the sawn silicon sheet allowed the etching solution to penetrate the thin silicon sheet and improve the light trapping capability thereof. Although this etching method was effective for sawed thin silicon sheets, it is not effective for improving the light trapping of direct-cast silicon sheets having a thickness less than 1000 micrometers because there is no saw damage on such directly cast silicon. Because there is no saw damage, these directly cast silicon sheets cannot be sufficiently etched by conventional etching solutions. Thus, there remains a need for a process to improve the light trapping capability of directly-cast silicon sheets having a thickness less than 1000 micrometers.

### SUMMARY

The disclosure provides a process for modifying a cast polycrystalline silicon sheet to decrease the light reflectance of a surface thereof. The cast polycrystalline silicon sheet has at least one structural feature resulting from the cast polycrystalline silicon sheet being directly cast to a thickness less than 1000 micrometers. The process comprises grit blasting the surface of the cast polycrystalline silicon sheet to give an abraded surface. The process further comprises chemically etching the abraded surface of the cast polycrystalline silicon sheet to give a chemically-etched, abraded surface. The light reflectance of the chemically-etched, abraded surface is decreased in comparison to the light reflectance of the surface of the cast polycrystalline silicon sheet before the step of grit blasting.

The disclosure also provides a process of forming and modifying the cast polycrystalline silicon sheet. This process in various embodiments comprises directly casting silicon to a thickness less than 1000 micrometers to form the cast polycrystalline silicon sheet. The cast polycrystalline silicon sheet has a surface having at least one structural feature resulting from being directly cast to a thickness less than 1000 micrometers. The process may further comprise grit blasting the surface of the cast polycrystalline silicon sheet to give an abraded surface. The process may also comprise chemically etching the abraded surface of the cast, polycrystalline silicon sheet to give a chemically-etched, abraded surface. The light reflectance of the chemically-etched, abraded surface is decreased in comparison to the light reflectance of the surface of the cast polycrystalline silicon sheet before the step of the grit blasting.

### BRIEF DESCRIPTION OF THE DRAWINGS

For understanding the present disclosure, reference may be made to the following detailed description taken in connection with the accompanying drawings.

FIG. 1 is a front perspective view of an apparatus used for grit blasting in accordance with one embodiment; and

FIG. 2 is an inside view of an apparatus used for grit blasting shown in FIG. 1 in accordance with one or more embodiments.

### DETAILED DESCRIPTION

The disclosed process advantageously reduces the amount of silicon lost from the silicon sheet when compared to the amount of material lost from the sawing of large silicon ingots. Conventional single-crystal and polycrystalline silicon ingots require subsequent wire sawing of the ingot into thin silicon sheets, leading to loss of material, e.g., approximately 50% kerf width. Furthermore, the disclosed process forms a modified surface having decreased light reflectance when compared to surfaces of directly cast silicon sheets. Finally, the disclosed process is fast and inexpensive.

It has been surprisingly realized that the cast polycrystalline silicon sheet formed by direct casting may lack sufficient mechanically induced strain to be etched by conventional etching solutions. As such, the inventors have realized that by grit blasting the surface of the cast polycrystalline silicon sheet, enough mechanically induced strain can occur in the abraded surface to allow sufficient chemical etching.

A process for modifying the surface of the cast polycrystalline silicon sheet is disclosed. The cast polycrystalline silicon sheet has at least one structural feature uniquely resulting from the cast polycrystalline silicon sheet being directly cast to a thickness less than 1000 micrometers. The process further comprises grit blasting the surface of the cast polycrystalline silicon sheet to give an abraded surface. The abraded surface of the cast polycrystalline silicon sheet to give a chemically-etched, abraded surface. The light reflectance of the chemically etched, abraded surface is decreased in comparison to the light reflectance of the surface of the cast polycrystalline silicon sheet before grit blasting.

In another embodiment, a process is directed to a process for forming and modifying the silicon sheet comprises directly casting silicon to form the cast polycrystalline silicon sheet with a thickness less than 1000 micrometers. The cast polycrystalline silicon sheet has a surface having at least one structural feature uniquely resulting from being directly cast to a thickness less than 1000 micrometers. The light reflectance of the chemically etched, abraded surface of the cast polycrystalline silicon sheet is decreased in comparison to the light reflectance of the surface of the cast polycrystalline silicon sheet before grit blasting.

According to various embodiments, the silicon to be cast may be pure (such as intrinsic or i-type silicon) or doped (such as silicon containing an n-type or p-type dopant, such as phosphorous or boron, respectively). In at least one embodiment of the disclosure, the silicon to be cast comprises at least one dopant selected from boron, phosphorous, or aluminum (B, P, or Al). The amount of dopant present in the silicon to be cast may be chosen based on the desired dopant concentration and distribution in the resultant sheet and may depend on the final use of the article. In at least one further embodiment, the silicon to be cast may comprise at least one non-semiconducting element that may form a semiconducting alloy or compound with another element.

In at least one further embodiment, the silicon to be cast may have low contaminant levels. For example, the silicon to be cast may comprise less than 1 ppm of iron, manganese, and chromium, and/or less than 1 ppb of vanadium, titanium, and zirconium. The silicon to be cast may also comprise less than 10¹⁵ atoms/cm³ of nitrogen and/or less than 10¹⁷ atoms/cm³ of carbon. In at least one embodiment, the silicon to be cast may be photovoltaic-grade or purer silicon.

The term “polycrystalline” refers to any material comprising a plurality of crystal grains. For example, polycrystalline materials may have grain sizes ranging from 0.1 to 500 um, though smaller grain sizes, including nano-crystalline grain sizes, are also contemplated.

The term “cast” refers to the fact that the cast polycrystalline silicon sheet is formed on or in a mold, such that the cast polycrystalline silicon sheet was shaped by at least one surface of the mold at some point during its formation. The term “mold” refers to a physical structure that can influence the final shape of the cast polycrystalline silicon sheet. In one embodiment, molten or solidified silicon need not necessarily physically contact the surface of the mold. However, in another embodiment, contact may occur between a surface of the mold and the molten silicon to be cast.

The surface of the cast polycrystalline silicon sheet may further be defined as a surface solidified on the mold. The surface solidified on a mold is a surface which directly contacts the mold during the casting process, and is later separated from the mold. The surface solidified on the mold may exhibit a texture that complements the texture of the mold it was solidified upon. For example, if the mold has a plurality of protrusions on its surface, the cast polycrystalline silicon sheet's surface solidified on the mold will have a plurality of indentations substantially complementary to the plurality of protrusions on the mold surface. Alternative textures are also contemplated.

In one embodiment, the cast polycrystalline silicon sheet was solidified on a mold during an exocasting process. The phrase “exocasting process” refers to a process where a mold is dipped into molten silicon and the cast polycrystalline silicon sheet forms on the outside of the mold. In particular, the mold is immersed in the molten silicon for a period of time sufficient to form a solid layer of the silicon over the external surface of the mold. The mold is withdrawn with the solid layer of silicon from the molten silicon adjacent to the mold. The solid layer of silicon is separated from the mold to form the cast polycrystalline silicon sheet. Several examples of an exocasting process capable of forming the cast polycrystalline silicon sheet are described in patent publications U.S. Publication Patent Application Nos. 2010/0291380, 2009/0297395, 2010/0290946, which are hereby incorporated by reference. These disclosures relate generally to exocasting methods for forming polycrystalline semiconducting materials wherein a solid layer of semiconducting material is formed over an external surface of a mold that is dipped into a molten semiconducting material.

In another embodiment, the cast polycrystalline silicon sheet is produced using a Ribbon Growth on Substrate (RGS) method. The RGS method comprises casting silicon sheets directly on a moving substrate. Typically, the moving substrate moves under a crucible which contains molten silicon. The silicon crystallizes in a direction perpendicular to the direction of the moving substrate at a controllable rate. The crystallization speed is decoupled from the speed of the moving substrate.

In another embodiment, the cast polycrystalline silicon sheet is formed by casting sheets on a downward-facing surface of a temperature controlled surface. The temperature controlled surface is placed in contact with the free surface of a molten pool of silicon. Solid silicon nucleates and grows from the temperature controlled surface into the molten silicon until the desired thickness is achieved. The temperature controlled surface and the cast polycrystalline silicon sheet are then separated from the molten silicon, and the cast polycrystalline silicon sheet is removed from the temperature-controlled plate. The temperature controlled surface may be located on a roller having a plurality of peripheral surface protrusions. The roller may include a cooling system for cooling the protrusions when the mold is rotated and the surfaces of the cooled protrusions are dipped in the molten silicon material to form the cast polycrystalline silicon sheet. These methods are further described in U.S. Patent Publication No. 2003/0111105, which is hereby incorporated by reference.

In another embodiment, the cast polycrystalline silicon sheet is formed by contacting molten silicon with a forming surface of the mold for a period of time and providing a differential pressure regime such that the pressure at a portion of the forming surface is less than the pressure at the surface of the molten silicon. At least a portion of the forming surface the mold is at a temperature below the melting point of the molten silicon such that the solid layer of silicon forms adjacent to the forming surface of the porous mold. The solid layer of silicon may be detached from the forming surface by changing the differential pressure regime to form the cast polycrystalline silicon sheet. In certain embodiments, the pressure at the surface of the molten silicon is about atmospheric and the pressure at the forming surface is less than atmospheric. These methods are further described in U.S. Patent Publication No. 2012/0067273, which is hereby incorporated by reference.

The surface of the cast polycrystalline silicon sheet may be described as a virgin surface. The phrase “virgin surface” may refer to a surface that is “as cast” before undergoing any surface modification.

The phrase “virgin surface” may also refer to a surface that is free from post-casting mechanical texturization, such as texturization resulting from saw damage, grinding, cutting, trimming, abrasion, planarization and any other surface modification resulting from the application of mechanical force. The phrase “free of saw damage” means a surface that has not been modified by a saw, such as a wire saw conventionally used in cutting silicon ingots. Thus, the cast polycrystalline silicon sheet may be distinguished from silicon sheets made by sawing large ingots into thin slices.

The phrase “virgin surface” may also refer to a surface that has not been modified by a post-casting chemical etching or plasma treatment process. The phrase “chemical texturization” refers the effect on the surface characteristic(s) of the cast polycrystalline silicon sheet from the application of a chemical composition. Surface characteristic refers to the physical characteristics of the surface of the silicon sheet, such as surface roughness or light reflectivity. A variety of chemical compositions are contemplated for use in such chemical texturization processes, such as etching solutions comprising various acids and bases, examples of which are described below.

The surface of the cast polycrystalline silicon sheet has least one structural feature uniquely resulting from the cast polycrystalline silicon sheet being directly cast to a thickness less than 1000 micrometers. In one embodiment, the structural feature comprises a plurality of grains having a median grain size ranging from 0.1 to 5, from 0.5 to 3, or from 1 to 3 millimeters with 80% of the grain diameters of the plurality of grains varying from the median grain size by less than or equal to 50%. The median grain size of the cast polycrystalline silicon sheet can be determined based on image analysis of the liquid-facing face of cast polycrystalline silicon sheet whereupon a sufficient number of the grain boundaries are indicated by topographic relief resulting from different growth rates at those boundaries. Alternatively, the sheet can be prepared and measured in accordance with ASTM E-112.

The grain size, shape, and distribution often play a part in the performance of the cast polycrystalline silicon sheet where a more uniform grain size is often desirable. For example, the efficiency of photovoltaic cells may be improved by improving the uniformity of the grain size. The cast polycrystalline silicon sheet directly cast differs from those conventional silicon sheets manufactured with string-ribbon processes or edge-defined methods. More particularly, those conventional silicon sheets have larger grain sizes than the directly cast polycrystalline silicon sheets. For example, conventional silicon sheets may have grains with a length and width greater than 1 cm. Whereas direct casting methods grow grains substantially normal to the plane of the sheet, these conventional methods could grow parallel to the sheet. These different grain sizes can result in different performances.

The disclosed process may be utilized with one or more surfaces of the cast polycrystalline silicon sheet. The cast polycrystalline silicon sheet may include one or more major surfaces and one or more minor surfaces. The terms “major” and “minor” refer to relative percentages of each surface area relative to the total surface area of the cast polycrystalline silicon sheet. For example, a major surface may represent at least 10, 25, 30, 40, or 50% of the surface area of the cast polycrystalline silicon sheet, while a minor surface may represent less than 40, 30, 20, or 10% of the surface area of the cast polycrystalline silicon sheet. Each of the major and minor surfaces of the cast polycrystalline silicon sheet may be modified by the disclosed process.

In one embodiment, the cast polycrystalline silicon sheet has an average thickness ranging from 50 to 400, from 120 to 300, from 120 to 200, or from 120 to 160 micrometers (m). The phrase “average thickness” refers to the value of an average of the thicknesses of the cast polycrystalline silicon sheet across its surface area.

The cast polycrystalline silicon sheet may comprise any shape or form. Examples of such shapes and forms include cast polycrystalline silicon sheets that are smooth or textured; flat, curved, bent, planar, or angled; or are symmetric or asymmetric. The term “planar” indicates that the cast polycrystalline silicon sheet is substantially two-dimensional. The term “curved” indicates that the cast polycrystalline silicon sheet has curvature in at least one dimension. Examples of curved silicon sheets are those having cylindrical, semi-circular or elliptical shapes.

The cast polycrystalline silicon sheet typically exhibits a length-to-width ratio ranging from 1 to 10, 1 to 6, 1 to 3, from 1 to 2.5, from 1 to 2, from 1 to 1, or from 1 to 0.5, from 1 to 0.33, from 1 to 0.2, or from 1 to 0.1. Alternative shapes and sizes are also contemplated. In one embodiment, the cast polycrystalline silicon sheets may have a length or width ranging from 50 mm to 5 meters, from 50 mm to 1 m, or from 50 mm to 500 mm, or from 100 mm to 300 mm. In one specific embodiment, the dimensions of the cast polycrystalline silicon sheet are about 156 mm×156 mm

In one embodiment, the cast polycrystalline silicon sheet may be free-standing or as part of a sheet assembly. The term “free-standing” refers to the fact that the cast polycrystalline silicon sheet is not attached to any additional components. Alternatively, the term “free-standing” means that the cast polycrystalline silicon sheet is not integral with the mold. The cast polycrystalline silicon sheet may be loosely connected to the mold while it is being formed, but the cast polycrystalline silicon sheet is separated from the mold after it is formed. The cast polycrystalline silicon sheet may, however, be subsequently applied on a substrate for various applications, such as photovoltaic applications.

A sheet assembly refers to the fact that the cast polycrystalline silicon sheet is connected, attached, mounted, or provided adjacent to one or more additional components, such as a back cell connection, a removable support or scaffold. The removable support or scaffold could potentially be separated from the cast polycrystalline silicon sheet after the process is completed.

It is also contemplated that the cast polycrystalline silicon sheet may be trimmed to meet the specifications of the sheet assembly or other downstream application before or after the steps of grit blasting the surface of the cast polycrystalline silicon sheet and/or chemically etching the abraded surface of the cast polycrystalline silicon sheet.

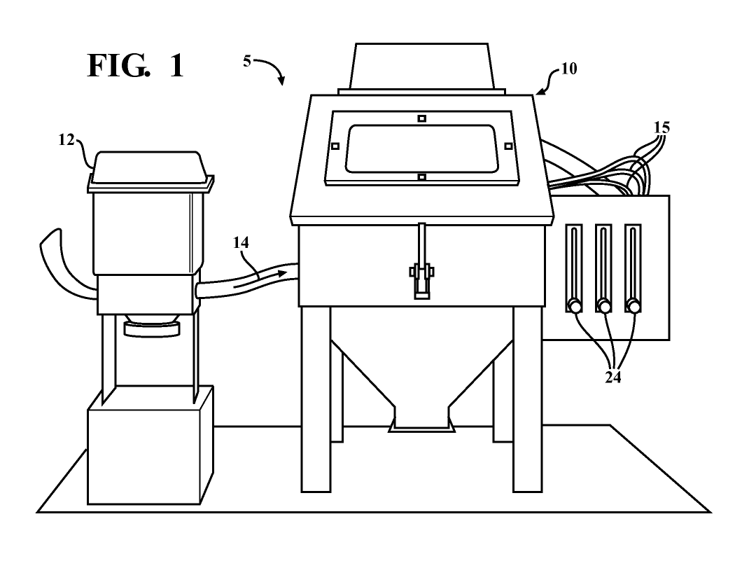

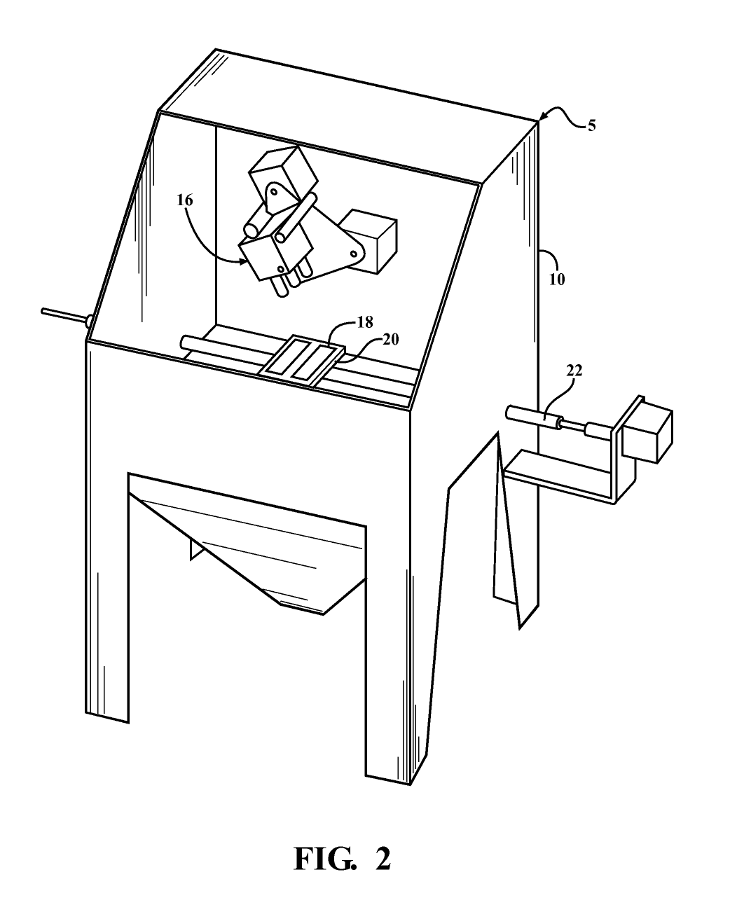

In one particular embodiment, the step of grit blasting the surface of the cast polycrystalline silicon sheet comprises grit blasting the surface of the cast polycrystalline silicon sheet with an abrading media in a carrier. Referring to FIGS. 1 and 2, the apparatus used for grit blasting 5 may further comprise an equipment enclosure 10, a media tank 12, media supply line 14, nozzle conduits, and at least one nozzle 16. The media tank is optionally pressurizable. The grit blasting apparatus may employ a gravity-fed, venturi-assisted delivery system. Such a system may use one or more flow meter-controlled compressed gas lines 15 that feed the venture nozzle 16. The media supply line 14 may be split into one or more lines for feeding the venture nozzle. The cast polycrystalline silicon sheet 18 may be attached to a vacuum chuck 20 and which is attached to a linear slide 22. The linear slide 22 may move the cast polycrystalline sheet 18 in predetermined patterns to ensure even grit blasting. The media tank 12 can hold the abrading media and may be optionally pressurized with the carrier and/or compressed gas, such as air. The pressurized carrier, abrading media, and/or compressed gas can then be forced through the at least one nozzle 16. The grit blasting apparatus 5 may be configured to mix a stream of the compressed gas with abrading media to grit blast the surface of the cast polycrystalline silicon sheet 18. The compressed gas can be injected into the media tank 12, which can then force a mix of the compressed air, carrier and/or abrading media through the at least one nozzle 16.

The apparatus used for grit blasting 5, (and each component thereof, i.e., equipment enclosure, media tank, tubing, at least one nozzle, vacuum chuck, and linear slide) may comprise materials that reduce contamination. In one embodiment, the apparatus used for grit-blasting may be free, or substantially free, from stainless steels, hardened carbon steels, and superalloys, which include Fe, Cr, V, Ti, Co, or Ni. These materials may contaminate the cast polycrystalline silicon sheet 18. In other words, the apparatus used for grit blasting 5 may comprise less than 10, 5, 3, 1, 0.5, or 0.1 wt. % of stainless steels, hardened carbon steels, and superalloys, which comprise Fe, Cr, V, Ti, Co, or Ni.

The apparatus used for grit blasting 5 may be manufactured from and comprise the same materials used in the abrading media. In other words, the equipment enclosure 10, media tank 12, media supply line 14, nozzle conduits, at least one nozzle 16, vacuum chuck 20, and/or linear slide 22 may each independently comprise vitreous silica, silicon, silicon carbide, aluminum oxide, quartz, or combinations thereof.

In one embodiment, the cast polycrystalline silicon sheet 18 may be mounted to the vacuum chuck 20 which carries the cast polycrystalline silicon sheet 18 to a position adjacent to the at least one nozzle 16 to begin the grit blasting process. The vacuum chuck 20 operates by attaching to the polycrystalline silicon sheet 18 using vacuum pressure. One or more passes of the cast polycrystalline silicon sheet 18 adjacent to the nozzle(s) may be taken in order to ensure sufficient abrasion. These passes may be facilitated by the linear slide 22. For example, the cast polycrystalline silicon sheet 18 may undergo 1, 2, 3, 4, 5, 6 or 7 grit blasting steps to form the abraded surface. Each grit blasting step may utilize different abrading media, may be conducted for varying durations, and may utilize different carriers.

As described above, the apparatus used for grit blasting 5 may comprise the at least one nozzle 16 to direct the abrading media toward the surface of the cast polycrystalline silicon sheet 18. Alternatively, the apparatus may use two, three, four, five, or more nozzles 16 to direct the abrading media toward the surface of the cast polycrystalline silicon sheet 18. The angle of the nozzles 16 may be controlled to ensure that the optimum amount of silicon is being removed from the cast polycrystalline silicon sheet 18 and to control the surface properties of the abraded surface of the cast polycrystalline silicon sheet 18. The angle of at least one nozzle 16 relative to the cast polycrystalline silicon sheet 18 may range from 30 to 90, from 45 to 80, or from 50 to 70 degrees. The shape and bore size of at least one nozzle 16 may be also be independently controlled to adjust the nozzle coverage and the speed of the carrier and/or abrading media.

In one or more embodiments, the abrading media is not recycled. In other embodiments, the abrading media is recycled. If the abrading media is recycled, the apparatus used for grit blasting 5 may contain a recycle collection system.

The abrading media typically comprises a grit comprising vitreous silica, silicon, silicon carbide, aluminum oxide, quartz, or combinations thereof. Alternatively, the abrading media may consist, or consist essentially of, vitreous silica, silicon, silicon carbide, aluminum oxide, quartz, or combinations thereof, in addition to one or more components that do not compromise the functionality or performance of the abrading media. In various embodiments where the abrading media consists essentially of vitreous silica, silicon, silicon carbide, aluminum oxide, quartz, or combinations thereof, the abrading material is free of, or includes less than 5, 2.5, 1, 0.5, or 0.1 wt. % of other components that affect the functionality of the abrading media. In other embodiments, the terminology “consisting essentially of” describes the abrading media being free of compounds that materially affect the overall performance of the abrading media. In certain embodiments, the abrading media may include a chelating agent. The chelating agent may prevent the formation of certain metal complexes on the cast polycrystalline silicon sheet 18.

The carrier can be liquid or gaseous. If the carrier is gaseous, the carrier may comprise air, N₂, CO₂, He, Ar, Ne, Kr, Xe, or combinations thereof. If the carrier is liquid, the abrading media can be mixed with the carrier to form a slurry. The slurry may be formed in the media tank 12 by combining the carrier, the abrading media, and the compressible gas. The slurry may then be directed through the at least one nozzle 16 to grit blast the surface of the cast polycrystalline silicon sheet. In embodiments where the slurry is formed, the carrier may comprise or consist of water which is free, or substantially free of metals that may contaminate the cast polycrystalline silicon sheet. For example, the water may contain less than 100, 50, 25, or 5 ppm metal content. Furthermore, the slurry may contain less than 100, 50, 25 or 5 ppm metal content.

The carrier may further comprise various additives, such as coolants, surfactants, pH buffering agents, acids, bases, and metal chelating agents to improve flow, prevent caking, or aid recycling or waste disposal.

Typically, the abrading media has an average diameter ranging from 1 to 200, from 5 to 100, or from 5 to 50 micrometers. The average diameter of the abrading media may be determined by sieving the abrading media to determine its mesh size in accordance with ASTM C136-06.

The abrading media typically has a high purity and comprises less than 1000, 100, 10, or 1 ppm transition metals. If the abrading media does not have a sufficient level of purity it can impede the chemical etching step, various cleaning steps, and downstream heat treatment steps.

The carrier typically has a volumetric flow rate ranging from 0.1 to 30 L/min per nozzle. Alternatively, the carrier has a volumetric flow rate ranging from 0.1 to 15, 0.5 to 10, or 0.5 to 8 L/min per nozzle. The volumetric flow rate of the carrier may be determined and controlled using conventional flow meter control technology. For example, one or more flow meters 24 can be used. The flow meters 24 may be connected to the media supply line 14 and/or one or more of the compressed gas lines 15.

The carrier is may be pressurized in a pressurizable media tank at a gauge back pressure ranging from 5 to 90, from 10 to 75, or from 10 to 30 psig. By back pressure, we are referring to the static system pressure before the nozzle 16 is opened.

In one or more embodiments, grit blasting the surface of the cast polycrystalline silicon sheet removes less than 10 micrometers in thickness of silicon from the cast polycrystalline silicon sheet. Alternatively, grit blasting the surface of the cast polycrystalline silicon sheet removes less than 8, less than 5, less than 3, or less than 1 micrometer. These ranges refer to the average thickness of the silicon removed from the cast polycrystalline silicon sheet when compared to the thickness of the cast polycrystalline silicon sheet before the step of grit blasting has been initiated.

In another embodiment, grit blasting the surface of the cast polycrystalline silicon sheet removes less than 1 wt. % of the cast polycrystalline silicon sheet based on the total weight of the cast polycrystalline silicon sheet before the step of grit blasting has been initiated. Alternatively, grit blasting the surface of the cast polycrystalline silicon sheet removes less than 0.5, less than 0.3, less than 0.1, or less than 0.05 wt. % of the cast polycrystalline silicon sheet based on the total weight of the cast polycrystalline silicon sheet before the step of grit blasting has been initiated. The amount of silicon removed from the cast polycrystalline silicon sheet during grit blasting can be determined by weighing the cast polycrystalline silicon sheet before and after the step of grit blasting, and comparing the weights thereof.

The process comprises chemically etching the abraded surface of the cast polycrystalline silicon sheet to give a cast polycrystalline silicon sheet that presents a chemically-etched, abraded surface. The step of chemically etching the abraded surface of the cast polycrystalline silicon sheet is typically carried out at a temperature ranging from 25 to 100, from 30 to 90, or from 65 to 85° C. The temperature may be controlled by circulating the etching solution through a thermal bath, such as a silicon oil bath.

A variety of etching solutions may be used to chemically etch the abraded surface of the cast polycrystalline silicon sheet. In one embodiment, the etching solution comprises HF, HNO₃, and water. Alternatively, the etching solution comprises NaOH and NaOCl. Alternatively still, the etching solution comprises HF and HNO₃. Alternatively, the etching solution may include other combinations of acids and bases. Both anisotropic and isotropic etching solutions may be used alone, or in combination. The term “isotropic” refers to fact that the etching reaction is the same in any direction. The term “anisotropic” refers to the fact that the etch rate in the direction normal to the surface is much higher than in directions parallel to the surface.

In one specific embodiment, chemically etching the abraded surface of the cast polycrystalline silicon sheet comprises contacting the abraded surface with an aqueous isotropic etch solution. Typically, the isotropic etch solution is acidic having a pH below 7, 6, 5, 4, 3, 2, or 1. Alternatively, the isotropic etch solution may be basic.

In another embodiment, chemically etching the abraded surface of the cast polycrystalline silicon sheet comprises contacting the abraded surface of the cast polycrystalline silicon sheet with an azeotropic solution comprising NaOH and NaOCl in a volume ratio ranging from 1:3 to 3:1. In other specific embodiments, the azeotropic solution may comprise NaOH and NaOCl in a volume ratio ranging from 1:2 or 2:1, or from 1:1.5 to 1.5 to 1.

In yet another embodiment, chemically etching the abraded surface of the cast polycrystalline silicon sheet comprises sequentially contacting the abraded surface with a first etching solution, a second etching solution, and a third etching solution. The term “sequentially” refers to the fact that the first etching solution contacts the abraded surface before the second etching solution, and that the second etching solution contacts the abraded surface before the third etching solution. However, in certain embodiments, the first etching solution may contact the abraded surface at the same time that second and third etching solutions contact the abraded surface, and that the second etching solution contacts the abraded surface at the same time that the third etching solution contacts the abraded surface.

The first etching solution, the second etching solution and the third etching solution are each different from one another in at least one property, such as concentration, composition, or pH. In one embodiment, the first etching solution comprises HF, HNO₃, and H₂O in a volume ratio ranging from 60:1:20 to 80:10:30 respectively; the second etching solution comprises HF and HNO₃ in a volume ratio ranging from 1:99 to 5:95 respectively; and the third etching solution comprises a buffering agent and hydrofluoric acid in a volume ratio ranging from 3:1 to 9:1 respectively. Alternatively, the first etching solution comprises HF, HNO₃, and H₂O in a volume ratio ranging from 65:3:23 to 75:7:27 respectively; the second etching solution comprises HF and HNO₃ in a volume ratio ranging from 2:98 to 4:96 respectively; and the third etching solution comprises a buffering agent and hydrofluoric acid in a volume ratio ranging from 5:1 to 7:1 respectively.

The chemically etching may be conducted for varying durations. The step of chemically etching the abraded surface of the cast polycrystalline silicon sheet typically has an overall duration ranging from 1 to 90, from 1 to 60, or from 1 to 30 minutes, based on the amount of time that the abraded surface of the cast polycrystalline silicon sheet contacts any of the above etching solutions. In one configuration, the abraded surface of the cast polycrystalline silicon sheet sequentially contacts the first etching solution for a time period ranging from 1 to 10 minutes, then contacts the second etching solution for a time period ranging from 0.1 to 3 minutes, and then contacts the third etching solution for a time period ranging from 0.01 to 0.5 minutes. Alternatively, the abraded surface of the cast polycrystalline silicon sheet sequentially contacts the first etching solution for a time period ranging from 3 to 7 minutes, then contacts the second etching solution for a time period ranging from 0.5 to 2 minutes, and then contacts the third etching solution for a time period ranging from 0.1 to 0.5 minutes.

Any of the above etching solutions may include an additional oxidizing agent which suppresses the formation of nitrogen oxides and, if appropriate, a surface-active substance selected from the group including polyfluorinated amines and sulphuric acids. The additional oxidizing agent may be selected from the group including hydrogen peroxide, ammonium peroxydisulphate, perchloric acid, and combinations thereof.

Chemically etching the abraded surface of the cast polycrystalline silicon sheet may be conducted on only a portion of the abraded surface, such as 10, 20, 30, 40, 50, 60, 70, 80 or 90% of the surface area of the abraded surface. Alternatively, the entire abraded surface of the cast polycrystalline silicon sheet may be chemically etched.

The step of chemically etching the abraded surface of the cast polycrystalline silicon sheet may be conducted by spraying, dipping, capillary coating, or meniscus coating the abraded surface. Alternatively, the step of chemically etching may be conducted with a hydrous liquid solution such that the cast polycrystalline silicon sheet are merged into the one or more etching solutions to chemically etch the abraded surface of the cast polycrystalline silicon sheet.

The process may further comprise the step of rinsing the abraded or chemically-etched surface with one or more rinsing solutions. The step of rinsing may be conducted after the grit blasting or after any of the previously described etching solutions contact the abraded surface of the cast polycrystalline silicon sheet. Any contamination caused by metals which may be present on the abraded surface may be converted into soluble compounds during the step of chemically etching and removed during the step of rinsing. Various numbers of rinsing steps are contemplated, such as 1, 2, 3, 4, 5, 6 or 7 rinsing steps. Each of these steps may utilize the same or different rinsing solutions.

One of the rinsing solutions may comprise a mixture of de-ionized water and hydrogen peroxide and/or ammonium hydroxide in a volume ratio ranging from 150:1:1 to 50:1:1 if ammonium hydroxide is included, or from 150:1 to 50:1 if no ammonium hydroxide is included. Another one of the rinsing solutions may comprise a mixture of hydrogen chloride, hydrogen peroxide, and deionized water in a volume ratio ranging from 150:1:1 to 50:1:1 if hydrogen chloride is included, or from 150:1 to 50:1 if no hydrogen chloride is included. Alternatively still, the rinsing solution may comprise diluted embodiments of the first, second, and third etching solutions where deionized water is combined with the acidic and/or basic components of the first, second, and third etching solutions are combined with deionized water in a volume ratio ranging from 150:1 to 50:1.

The surface of the cast polycrystalline silicon sheet before grit blasting and/or the chemically etched, abraded surface cast polycrystalline silicon sheet may be masked with various materials to prevent grit blasting or chemical etching of portions of the masked portions of the cast polycrystalline silicon sheet. The masking may comprise carbon nanotubes, graphite powders, fullerenes, solid carbon fibers, boron nitride, silicon carbide, silicone, oxides of silicon, aluminum, and other materials. The mask can be applied before the grit blasting with conventional spraying or coating techniques.

The abraded, chemically-etched surface of the cast polycrystalline silicon sheet has at least one different characteristic from the surface of the cast polycrystalline silicon sheet before the grit blasting, and the abraded surface of the cast polycrystalline silicon sheet. For example, each of these surfaces may include different light reflectivity or surface roughness values.

The surface of the cast polycrystalline silicon sheet before grit blasting typically comprises a light reflectance ranging from 35 to 50, or from 40 to 45%. The abraded surface of the cast polycrystalline silicon sheet typically comprises a light reflectance ranging from 15 to 30, or from 20 to 25%. The abraded, chemically-etched surface of the cast polycrystalline silicon sheet typically comprises a light reflectance ranging from 18 to 35, or from 20 to 30%. The light reflectance of the abraded, chemically-etched surface of the cast polycrystalline silicon sheet is less than the light reflectance of the surface of the cast polycrystalline silicon sheet before grit blasting by at least 10, 25, or 50%. The light reflectance of these surfaces may be determined as modified, or after cell processing, e.g., when used in optoelectric applications such as PV and LED applications.

The process may increase the efficiency of solar cells formed from the cast polycrystalline silicon sheets having the chemically-etched, abraded surface. The phrase “increase the efficiency” is intended to mean that the efficiency of solar cells formed from the cast polycrystalline silicon sheet may be greater than that of solar cells formed from materials made by processes not within the scope of this disclosure. As discussed above, the process may produce articles of silicon having fewer defects than other known methods. In various embodiments, solar cells formed from the cast polycrystalline silicon sheets made by the process may have an efficiency exceeding 13%, such as exceeding 17%, or exceeding 20%.

The following examples, illustrating the silicon sheets, are intended to illustrate various embodiments without limitation.

One or more of the values described above may vary by ±5%, ±10%, ±15%, ±20%, ±25%, etc. so long as the variance remains within the scope of the disclosure. Unexpected results may be obtained from each member of a Markush group independent from all other members. Each member may be relied upon individually and or in combination and provides adequate support for specific embodiments within the scope of the appended claims. The subject matter of all combinations of independent and dependent claims, both singly and multiply dependent, is herein expressly contemplated. The disclosure is illustrative including words of description rather than of limitation. Many modifications and variations of the present disclosure are possible in light of the above teachings, and the disclosure may be practiced otherwise than as specifically described herein.

As used herein, the singular forms “a,” “an” and “the” include plural referents unless the context clearly dictates otherwise. Thus, for example, reference to a “silicon sheet” includes examples having two or more such “silicon sheets” unless the context clearly indicates otherwise.

Ranges can be expressed herein as from “about” one particular value, and/or to “about” another particular value. When such a range is expressed, examples include from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred.

While various features, elements or steps of particular embodiments may be disclosed using the transitional phrase “comprising,” it is to be understood that alternative embodiments, including those that may be described using the transitional phrases “consisting” or “consisting essentially of” are implied. Thus, for example, implied alternative embodiments to a process comprising grit blasting and chemically etching include embodiments where a process consists of grit blasting and chemically and embodiments where a process consists essentially of grit blasting and chemically etching.

It is also noted that recitations herein refer to a component being “configured” or “adapted to” function in a particular way. In this respect, such a component is “configured” or “adapted to” embody a particular property, or function in a particular manner, where such recitations are structural recitations as opposed to recitations of intended use. More specifically, the references herein to the manner in which a component is “configured” or “adapted to” denotes an existing physical condition of the component and, as such, is to be taken as a definite recitation of the structural characteristics of the component.

What is claimed is:

1. A process for modifying a surface of a cast polycrystalline silicon sheet to decrease light reflectance of the surface, wherein the cast polycrystalline silicon sheet has at least one structural feature resulting from the cast polycrystalline silicon sheet being directly cast to a thickness less than 1000 micrometers, said process comprising:
grit blasting the surface of the cast polycrystalline silicon sheet to give an abraded surface; and
chemically etching the abraded surface of the cast polycrystalline silicon sheet to give a chemically-etched, abraded surface, wherein the light reflectance of the chemically-etched, abraded surface is decreased in comparison to the light reflectance of the surface of the cast polycrystalline silicon sheet before the grit blasting.

2. The process as set forth in claim 1, wherein before the grit blasting, the surface of the cast polycrystalline silicon sheet comprises (a) a virgin surface; (b) a surface free from mechanical texturization; (c) a surface free from chemical etching; (d) a surface which was solidified on a mold during an exocasting process; or (e) any combination of at least two of (a), (b), (c), and (d).

3. The process as set forth in claim 1, wherein the structural feature of the cast polycrystalline silicon sheet comprises a plurality of grains wherein the median grain diameter of the plurality of grains ranges from 0.1 to 5 millimeters with 80% of the diameters of the plurality of grains varying from the median grain diameter by less than or equal to 50%.

4. The process as set forth in claim 1, wherein (a) the cast polycrystalline silicon sheet has an average thickness ranging from 50 to 400 micrometers; (b) the cast polycrystalline silicon sheet has a length-to-width ranging from 1 to 10; or (c) both (a) and (b).

5. The process as set forth in claim 1, wherein (a) grit blasting the surface of the cast polycrystalline silicon sheet removes less than 10 micrometers in thickness of silicon from the silicon sheet; (b) grit blasting the surface of the cast polycrystalline silicon sheet removes less than 1 wt. % of the cast polycrystalline silicon sheet based on the total weight of the cast polycrystalline silicon sheet before grit blasting; or (c) both (a) and (b).

6. The process as set forth in claim 1, wherein grit blasting the surface of the cast polycrystalline silicon sheet comprises grit blasting the surface of the cast polycrystalline silicon sheet with an abrading media in a carrier, wherein the abrading media comprises a grit comprising vitreous silica, silicon, silicon carbide, aluminum oxide, quartz, or combinations thereof

7. The process as set forth in claim 6, wherein (a) the abrading media has an average diameter ranging from 1 to 200 micrometers; (b) the abrading media has a purity above 90 based on the total weight of the abrading media; or (c) both (a) and (b).

8. The process as set forth in claim 6, wherein the abrading media is directed at the surface of the cast polycrystalline silicon sheet through at least one nozzle, and wherein (a) the carrier has a volumetric flow rate ranging from 0.1 to 30 L/min per nozzle; or (b) the carrier is pressurized at a gauge pressure ranging from 5 to 90 psi; or (c) both (a) and (b).

9. The process as set forth in claims 6, wherein the carrier is a liquid or a gas.

10. The process as set forth in claim 1, wherein chemically etching the abraded surface of the cast polycrystalline silicon sheet comprises contacting the abraded surface with an aqueous isotropic etch solution, wherein the aqueous isotropic etch solution is acidic.

11. The process as set forth in claim 1, wherein chemically etching the abraded surface of the cast polycrystalline silicon sheet comprises sequentially contacting the abraded surface with a first etching solution, a second etching solution, and a third etching solution, wherein the first etching solution, the second etching solution, and the third etching solution are each different from one another.

12. The process as set forth in claim 11, wherein the first etching solution comprises HF, HNO₃, and H₂O in a volume ratio ranging from 60:1:20 to 80:10:30 respectively; the second etching solution comprises HF and HNO₃ in a volume ratio ranging from 1:99 to 5:95 respectively; and the third etching solution comprises a buffering agent and hydrofluoric acid in a volume ratio ranging from 3:1 to 9:1 respectively; and wherein the abraded surface of the cast polycrystalline silicon sheet sequentially contacts the first etching solution for a time period ranging from 1 to 10 minutes, then contacts the second etching solution for a time period ranging from 0.1 to 3 minutes, and then contacts the third etching solution for a time period ranging from 0.01 to 0.5 minutes.

13. The process as set forth in claim 11, wherein the first etching solution comprises NaOH and NaOCl in a volume ratio ranging from 1:3 to 3:1.

14. A cast polycrystalline silicon sheet presenting a chemically-etched, abraded surface, wherein the light reflectance of the chemically-etched, abraded surface is decreased in comparison to the light reflectance of the surface of the cast polycrystalline silicon sheet before the grit blasting, the cast polycrystalline silicon sheet having been modified by the process of any preceding claim.

15. A process for forming and modifying a cast polycrystalline silicon sheet to decrease light reflectance of a surface of the cast polycrystalline silicon sheet, said process comprising:
directly casting silicon to form the cast polycrystalline silicon sheet having a thickness less than 1000 micrometers, wherein the surface of the polycrystalline silicon sheet has at least one structural feature resulting from being directly cast to the thickness less than 1000 micrometers;
grit blasting the surface of the cast polycrystalline silicon sheet to give an abraded surface; and
chemically etching the abraded surface of the cast polycrystalline silicon sheet to give a chemically-etched, abraded surface, wherein the light reflectance of the chemically-etched, abraded surface is decreased in comparison to the light reflectance of the surface of the cast polycrystalline silicon sheet before the grit blasting.

16. The process as set forth in claim 15, wherein before grit blasting, the surface of the cast polycrystalline silicon sheet comprises (a) a virgin surface; (b) a surface free from mechanical texturization; (c) a surface free from chemical etching; (d) a surface which was solidified on a mold during an exocasting process; or (e) any combination of at least two of (a), (b), (c) and (e).
